(19) United States
(12) Patent Application Publication
(10) Pub. No.: US 2014/0251425 A1
(43) Pub. Date: Sep. 11, 2014

(54) Heterostructure Si Solar Cells Using Wide-Bandgap Semiconductors

(71) Applicant: ARIZONA BOARD OF REGENTS, A BODY CORPORATION OF THE STATE OF ARIZONA, Scottsdale, AR (US)

(72) Inventors: Yong-hang Zhang, Scottsdale, AZ (US); Jing-Jing Li, Tempe, AZ (US); Ding Ding, Tempe, AZ (US)

(73) Assignee: Arizona Board of Regents, A Body Corporate of the State of Arizona, Scottsdale, AZ (US)

(21) Appl. No.: 14/232,027

(22) PCT Filed: Sep. 20, 2012
(86) PCT No.: PCT/US12/56237

§ 371 Date: Jan. 10, 2014

Related U.S. Application Data
(60) Provisional application No. 61/537,449, filed on Sep. 21, 2011.

(51) Int. Cl. H01L 31/074; H01L 31/02; H01L 31/0236

(52) U.S. Cl. CPC H01L 31/074; H01L 31/02363; H01L 31/02008
USPC 136/256; 136/258

(57) ABSTRACT

To improve the efficiency of heterostructure silicon photovoltaic devices, II-VI wide bandgap semiconductor layers can replace the TCO/doped amorphous silicon/intrinsic amorphous silicon layers on the front side or on both sides of the silicon bulk layer. For example, photovoltaic devices are described containing a first contact electrode; a first doped II-VI semiconductor layer disposed over the first contact electrode; a doped crystalline silicon layer disposed over the first doped II-VI semiconductor layer; and a second contact electrode disposed over the doped silicon layer, where one of the doped crystalline silicon layer and the first doped II-VI semiconductor layer is n-doped N and the other is p-doped.

### PRIORITY CLAIM

This application claims priority to U.S. Provisional Patent Application Ser. No. 61/537,449 filed Sep. 21, 2011, incorporated by reference herein in its entirety.

### STATEMENT OF GOVERNMENT SUPPORT

The invention described herein was made in part with government support under grant number 1002114, awarded by the National Science Foundation; and grant number FA9453-08-2-0228, awarded by the Air Force Research Laboratory (Space Vehicles Directorate Grant). The United States Government has certain rights in the invention.

### BACKGROUND OF THE INVENTION

Heterostructure silicon photovoltaic devices have achieved high efficiency with reduced costs. The introduction of heterojunctions in silicon photovoltaic devices effectively prevents minority carrier recombination at the front and back contacts, achieving high efficiency for thin devices. The structure of state of the art heterojunction with intrinsic thin layer (HIT) photovoltaic devices is shown in FIG. 1 [1-3]. It comprises of, in the order stated, layer front contact grids (1), a transparent conductive oxide (TCO) layer (2), a p-doped amorphous silicon (a-Si) layer (3), an intrinsic amorphous silicon layer (4), an n-doped monocrystalline silicon bulk layer (5), an intrinsic amorphous silicon layer (6), an n-doped amorphous silicon layer (7), a TCO layer (8) and back contact grids (9). The combination of TCO/doped amorphous silicon/intrinsic amorphous silicon layers passivate the silicon bulk layer from surface recombination and contact recombination.

However, it is expensive to use a TCO layer, such as indium tin oxide (ITO), for light transmission and current transport due to the high refractive index and low mobility of amorphous silicon. The absorption of TCO/doped amorphous silicon/intrinsic amorphous silicon layers causes some efficiency loss. In addition, the amorphous silicon is subject to light induced degradation after hydrogen passivation.

### SUMMARY OF THE INVENTION

To solve the aforementioned problems and further improve the efficiency, II-VI wide bandgap semiconductor layers are provided to replace the TCO/doped amorphous silicon/intrinsic amorphous silicon layers on the front side or on both sides of the silicon bulk layer.

Accordingly, in one aspect the invention provides photovoltaic devices comprising a first contact electrode; a first doped II-VI semiconductor layer disposed over the first contact electrode; a doped crystalline silicon layer disposed over the first doped II-VI semiconductor layer; and a second contact electrode disposed over the doped silicon layer, wherein one of the doped crystalline silicon layer and the first doped II-VI semiconductor layer is n-doped and the other is p-doped.

### BRIEF DESCRIPTION OF THE DRAWINGS

FIG. 1 is a cross section view of a HIT photovoltaic device in a prior art.

FIG. 2a is a cross section view of the photovoltaic device with one II-VI semiconductor layer and without a TCO layer.

FIG. 2b is a cross section view of the photovoltaic device with one II-VI semiconductor layer and a TCO layer.

FIG. 3a is a cross section view of the photovoltaic device with two II-VI semiconductor layers and without a TCO layer.

FIG. 3b is a cross section view of the photovoltaic device with two II-VI semiconductor layers and a TCO layer.

FIG. 4 is a side elevation view of the photovoltaic device in the first example and the corresponding band alignment.

FIG. 5 is a side elevation view of the photovoltaic device in the second example and the corresponding band alignment.

FIG. 6 is a side elevation view of the photovoltaic device in the third example and the corresponding band alignment.

FIG. 7 shows E_{g}^{x} and E_{g}^{Γ} (eV) for BeₓZn₁₋ₓSe as a function of Be composition.

FIG. 8 is a side elevation view of the photovoltaic device in the fourth example and the corresponding band alignment.

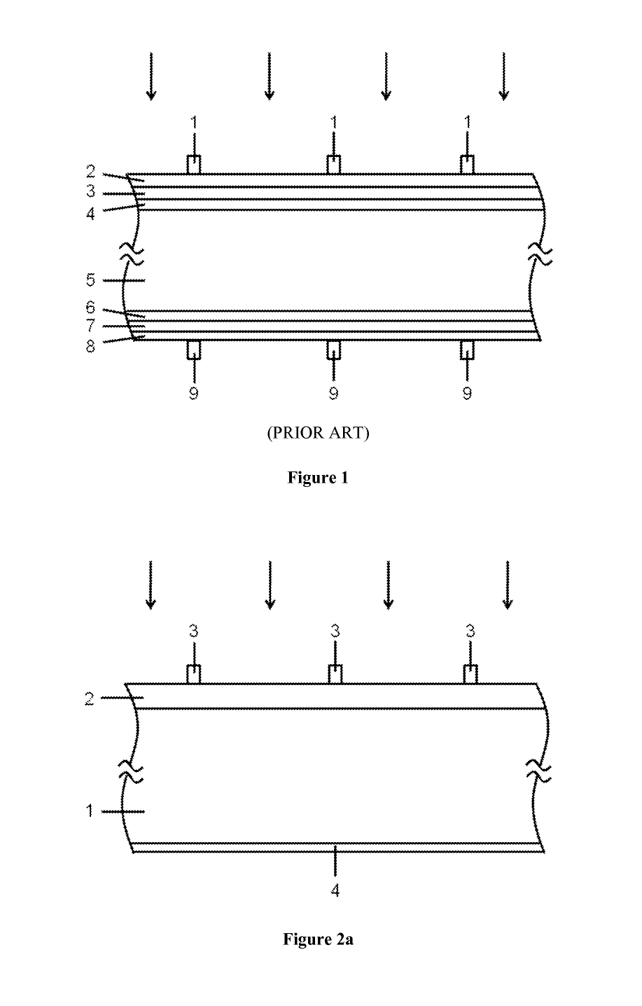

### DETAILED DESCRIPTION OF THE INVENTION

In a first aspect, the present invention provides photovoltaic devices comprising:
a first contact electrode;
a first doped II-VI semiconductor layer disposed over the first contact electrode;
a doped crystalline silicon layer disposed over the first doped II-VI semiconductor layer; and
a second contact electrode disposed over the doped silicon layer,

wherein one of the doped crystalline silicon layer and the first doped II-VI semiconductor layer is n-doped and the other is p-doped.

The advantages of using II-VI wide bandgap semiconductor layers instead of the

TCO/doped amorphous silicon/intrinsic amorphous silicon layers of prior devices can be summarized as follows:
1. Lower optical absorption and higher Isc due to large bandgaps, low carrier concentration with high mobility. The ITO and a-Si layers in HIT structure have 13.8% absorption loss while 636 nm ZnSe 1/(42) AR layer has only 5.5% absorption loss, an 8% absorption reduction;
2. Smaller series resistance and contact grid area because thicker II-VI layers can be used without adding much absorption losses. For example, the II-VI layer can be thicker than the 5-10 nm thick a-Si layer or a+Si layer in a HIT structure;
3. No expensive transparent conducting oxide (TCO) such as ITO;
4. Better interface with fewer dangling bonds, especially for lattice-matched ZnS/Si interface;
5. Much higher barriers for minority carriers, resulting in even higher Voc and lower temperature coefficient of the cell efficiency;
6. Maintain low refractive indices of II-VI semiconductors for efficient light trapping and reduced reflection;
7. Less manufacturing cost due to fewer layers;
8. Long-term stability of the cell efficiency without the use of hydrogen passivation; and
9. Low growth temperature (<350° l C.) for II-VI single crystals without affecting the underlying Si and forming a good interface.

The II-VI semiconductor layers described herein can be grown on a silicon bulk layer with high quality, and they can be doped with one or more dopants as is familiar to those skilled in the art. For example, ZnSe can be grown on Si using MBE (see e.g., Park and Mar, Appl. Phys. Lett., 48, 529, (1986); Mino et al., J. Appl. Phys., 58, 793, (1985); and Bringans et al. Phys. Rev. B 45, 13400 (1992)); ZnTe can be grown on Si using MBE (see e.g., de Lyon et al., Appl. Phys. Lett., 63,818, (1993)); ZnTe can be grown on Si using OMVPE (see e.g., Wang and Bhat, J. Electron. Mater., 24, 451, (1995); and ZnTe can be grown on Si using MOCVD (see e.g., Shan et al. J. Vac. Sci. Technol. A, 20, 1886, (2002)).

In certain embodiments, the first contact electrode is a “front” contact electrode of a photovoltaic device. “Front” as used herein refers to the surface of the photovoltaic devices upon which incident light is intended to be directed, or is actually directed when in operation.

In certain embodiments, a back surface field layer is disposed between the doped crystalline silicon layer and the second contact electrode. In certain embodiments, the back surface field layer is a second doped Si layer disposed between the doped crystalline silicon layer and the second contact electrode, such that the second doped Si layer is of the same doping type (i.e., both n-doped or both p-doped) as the doped crystalline silicon layer. When present, the second doped Si layer can be n⁺- or p⁺-doped while the doped crystalline silicon layer can be n⁻ or p⁻ doped, respectively.

Alternatively, the back surface field layer can be a second doped II-VI semiconductor layer disposed between the doped crystalline silicon layer and the second contact electrode, such that the second doped II-VI semiconductor layer is of the same doping type as the doped crystalline silicon layer. For example, both the doped crystalline silicon layer and the second doped II-VI semiconductor layer can be n-doped while the first doped II-VI semiconductor layer can be p-doped. Alternatively, both the doped crystalline silicon layer and the second doped II-VI semiconductor layer can be p-doped while the first doped II-VI semiconductor layer can be n-doped.

Each of the doped II-VI semiconductors, when present, can independently comprise a doped (BeZn)(SSeTe) alloy layer. Examples of such alloy layers include, but are not limited to ZnTe, ZnSe, ZnS, or BeₓZn₁₋ₓSe, wherein x is greater than 0 and less than 1 (e.g., Be_{0.45}Zn_{0.55}Se).

In one embodiment, the first doped II-VI semiconductor layer comprises ZnSe, ZnTe, or BeₓZn₁₋ₓSe, wherein x is greater than 0 and less than 1 (e.g., Be_{0.45}Zn_{0.55}Se),In another embodiment, the first doped II-VI semiconductor layer comprises ZnSe. In another embodiment, the first doped II-VI semiconductor layer comprises ZnTe. In another embodiment, the first doped II-VI semiconductor layer comprises BeₓZn₁₋ₓSe, wherein x is greater than 0 and less than 1 (e.g., Be_{0.45}Zn_{0.55}Se).

In another embodiment, the second doped II-VI semiconductor layer comprises ZnSe, ZnTe, or BeₓZn₁₋ₓSe, wherein x is greater than 0 and less than 1 (e.g., Be_{0.45}Zn_{0.55}Se). In another embodiment, the second doped II-VI semiconductor layer comprises ZnSe. In another embodiment, the second doped II-VI semiconductor layer comprises ZnTe. In another embodiment, the second doped II-VI semiconductor layer comprises BeₓZn₁₋ₓSe, wherein x is greater than 0 and less than 1 (e.g., Be_{0.45}Zn_{0.55}Se). In another embodiment, the second doped II-VI semiconductor layer comprises BeₓZn₁₋ₓSe, wherein x is greater than 0 and less than or equal to 0.5; or greater than 0 and less than or equal to 0.4; or greater than 0 and less than or equal to 0.3; or greater than 0 and less than or equal to 0.2; or greater than 0 and less than or equal to 0.1; or greater than or equal to 0.1 and less than 1; or greater than or equal to 0.2 and less than 1; or greater than or equal to 0.3 and less than 1; or greater than or equal to 0.4 and less than 1; or greater than or equal to 0.5 and less than 1; or greater than or equal to 0.6 and less than 1; or greater than or equal to 0.7 and less than 1; or greater than or equal to 0.8 and less than 1.

Each of the doped II-VI semiconductor layers can be pseudomorphically strained or partially relaxed to silicon. Further, each of the doped II-VI semiconductor layers can have bandgaps larger than silicon, e.g., between about 2.27 eV and about 3.7 eV. In certain embodiments, each of the doped II-VI semiconductor layers can have bandgaps between about 2.27 eV and 3.5 eV; or 2.27 eV and 3.0 eV; or 2.27 eV and 2.75 eV; or 2.27 eV and 2.50 eV; or 2.50 eV and 3.7 eV; or 2.75 eV and 3.7 eV; or 3.0 eV and 3.7 eV; or 3.25 eV an 3.7 eV. Further, in any of the preceding embodiment, each of the first doped II-VI semiconductor layer and the second doped II-VI semiconductor layer can, independently, have a thickness suitable for its intended purpose. In certain examples, each of the II-VI layers can have a thickness between about 10 nm and about 1000 nm; or about 10 nm and about 500 nm; or about 10 nm and about 400 nm; or about 10 nm and about 300 nm; or about 10 nm and about 200 nm; or about 10 nm and about 100 nm. For example, each of the II-VI semiconductor layers can have an optical thickness equal to a quarter of the center wavelength of the solar spectrum to enhance the light transmission into the silicon layer.

In any of the preceding embodiments, a transparent conductive oxide layer may be disposed between the first doped II-VI semiconductor layer and the first contact electrode, and may assist in current transport. Suitable transparent conductive oxide (TCO) layer layers include, but are not limited to TCOs having a bandgap between about 3 eV and 5 eV, such as indium tin oxide, zinc oxide, and indium zinc oxide. The thickness of the TCO will depend on the overall device design, for example the thickness of the II-VI layer and its conductivity. For example, the TCO can have a thickness between about 5 nm and about 5000 nm. In other examples, the TCO can have a thickness between about 10 nm and about 1000 nm; or between about 25 nm and about 1000 nm; or between about 50 nm and about 1000 nm; or between about 100 nm and about 1000 nm; or between about 50 nm and about 5000 nm; or between about 100 nm and about 5000 nm; or between about 250 nm and about 5000 nm; or between about 500 nm and about 5000 nm; or between about 1000 nm and about 5000 nm.

The doped crystalline silicon layer used in the preceding aspects and embodiments may comprise single crystalline silicon, multicrystalline silicon, or polycrystalline silicon. In one embodiment, the doped crystalline silicon layer comprises single crystalline silicon. In another embodiment, the doped crystalline silicon layer comprises multicrystalline silicon. In another embodiment, the doped crystalline silicon layer comprises polycrystalline silicon. In any of the preceding embodiments, the doped crystalline silicon layer can have a thickness suitable for its intended purpose. In certain examples, the doped crystalline silicon layer can have a thickness between about 100 nm and about 50 μm; or about 10 nm and about 10 μm; or about 10 nm and about 1 μm; or about 10 nm and about 500 nm; or about 10 nm and about 250 nm; or about 10 nm and about 100 nm; or about 100 nm and about 50 μm; or about 1 um and about 50 μm; or about 1 um and about 10 μm.

Each surface of the doped crystalline silicon layers may be textured. In certain embodiments, the surface of the doped crystalline silicon layer in contact with the first doped II-VI semiconductor layer is textured. In certain embodiments, the surface of the doped crystalline silicon layer in contact with the second contact electrode or the second doped II-VI semiconductor layer is textured. In certain other embodiments, the surface of the doped crystalline silicon layer in contact with the first doped II-VI semiconductor layer, and the surface of the doped crystalline silicon layer in contact with the second contact electrode or the second doped II-VI semiconductor layer are each textured.

The first contact electrode is a metal grid, and the second contact electrode is a metal grid, one or more point metal contacts, or a continuous metal contact layer. Such metal grids, contacts, and contact layers may be any suitable feature known to those skilled in the art.

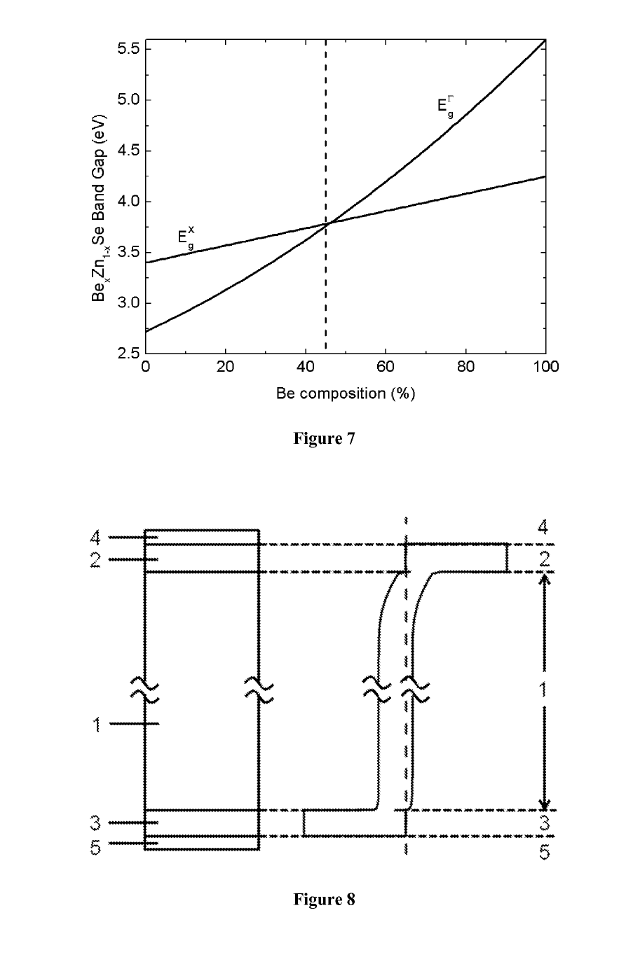

In one particular example, the photovoltaic device comprises, the first contact electrode; a first doped Be_{0.45}Zn_{0.55}Se layer disposed over the first contact electrode; and the doped crystalline silicon layer disposed over the first doped Be_{0.45}Zn_{0.55}Se layer. Such structures can be prepared by deposition of Be_{0.45}Zn_{0.55}Se on Si. In addition to all the advantages of a II-VI/Si/II-VI (e.g., ZnSe/Si/ZnTe) design discussed herein, this structure may use a ternary II-VI alloy that is perfectly lattice matched to Si with a defect-free interface. Furthermore, Be_{0.45}Zn_{0.55}Se is an indirect band material with bandgap about 3.7 eV (see FIG. 7), therefore the absorption loss is negligible. This design is expected to achieve even higher efficiency due to much longer carrier lifetime in n-type Si and much better interface properties.

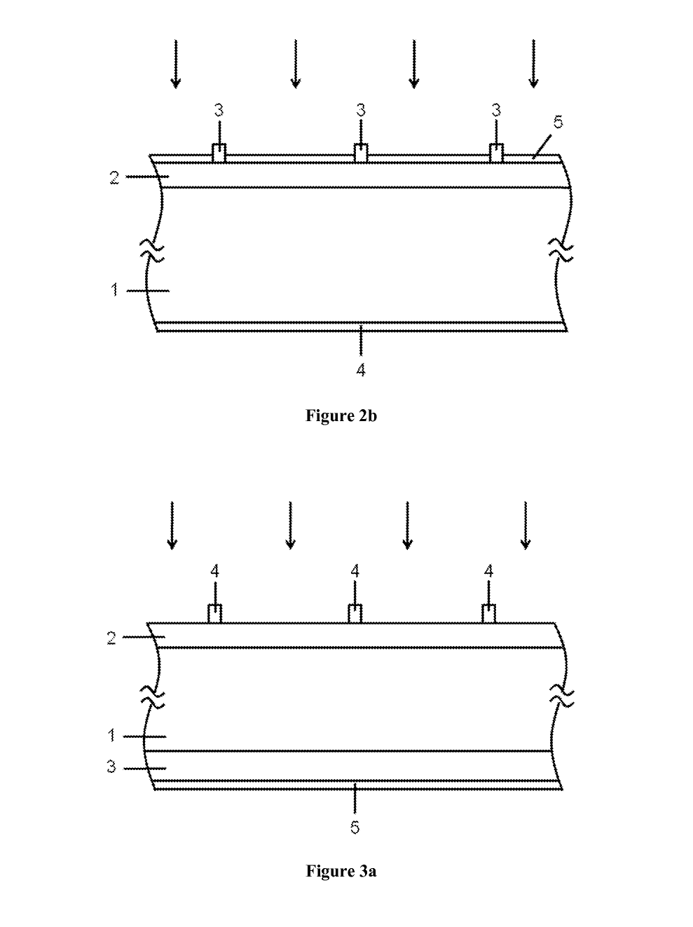

An exemplary photovoltaic device comprising a II-VI wide bandgap semiconductor layer is shown in FIG. 2a. It comprises, in the order stated, a front contact electrode (3), a II-VI semiconductor window layer of one type of doping (2), a crystalline Si bulk layer with the other type of doping (1) and a back contact electrode (4) in contact with their adjacent layers, wherein the thickness of the II-VI semiconductor layer is made to reduce the series resistance and as an anti-reflection coating. If the conductivity of the II-VI semiconductor layer is not high enough, a transparent conductive oxide layer (5) as shown in FIG. 2b can be added on top of the II-VI semiconductor layer for current transport and light transmission. In one embodiment, the window layer (2) (i.e., the first doped II-VI semiconductor layer) may comprise or consist essentially of n-ZnSe and the crystalline Si bulk layer (1) comprises or consists essentially of p-Si. In another embodiment, the window layer (2) may comprise or consist essentially of p-ZnTe and the crystalline Si bulk layer (1) comprises or consists essentially of n-Si.

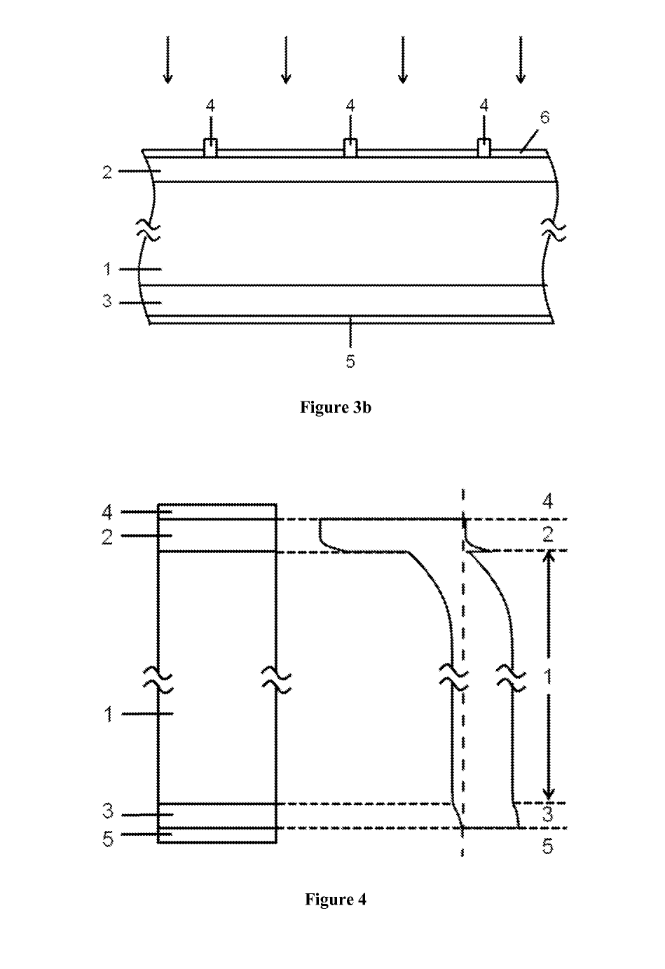

Another exemplary photovoltaic device comprising two II-VI wide bandgap semiconductor layers is shown in FIG. 3a. It comprises a front contact electrode (4), a II-VI semiconductor window layer of one type of doping (2), a crystalline Si bulk layer with the other type of doping (1), a second II-VI semiconductor layer of the same type of doping as the Si layer (3) and a back contact electrode (5). The thickness of the first II-VI semiconductor layer is made to reduce the series resistance and as an anti-reflection coating. The second II-VI semiconductor layer acts as a minority carrier blocking layer. If the conductivity of the first II-VI semiconductor layer is not high enough, as shown in FIG. 3b, a transparent conductive oxide layer (6) as shown in FIG. 3b can be added on top of the first II-VI semiconductor layer for current transport and light transmission. In one embodiment, the window layer (2) (i.e., the first doped II-VI semiconductor layer) may comprise or consist essentially of n-ZnSe and the crystalline Si bulk layer (1) comprises or consists essentially of p-Si. In another embodiment, the window layer (2) may comprise or consist essentially of p-ZnTe and the crystalline Si bulk layer (1) comprises or consists essentially of n-Si. In another embodiment, the window layer (2) may comprise or consist essentially of n-ZnSe and the crystalline Si bulk layer (1) comprises or consists essentially of p-Si; and the second II-VI semiconductor layer (3) comprises or consists essentially of p-ZnTe. In another embodiment, the window layer (2) may comprise or consist essentially of p-ZnTe, the crystalline Si bulk layer (1) comprises or consists essentially of n-Si, and the second II-VI semiconductor layer (3) comprises or consists essentially of n-ZnSe.

The material properties of some of the II-VI semiconductors and ITO are listed in Table 1 [3-16].

TABLE 1
Basic materials parameters of the II-VI semiconductors, a-Si, and ITO [3-16].

| | Be_{0.45}Zn_{0.55}Se | ZnSe | ZnTe | ITO |
|---|---|---|---|---|
| Bandgap E_{g} (eV) | 3.7 | 2.72 | 2.27 | 3.75 |
| Donor density N_{D} (cm⁻³) | | <2 × 10¹⁹ | <4 × 10¹⁸ | |
| Acceptor density N_{A} (cm⁻³) | | <10¹⁸ | <3 × 10¹⁹ | ~10²¹ |
| Mobility μₙ (cm²/Vs) | | 1500 | 600 | 30 |
| Mobility μₚ (cm²/Vs) | | 355 | 100 | |
| Resistivity ρₑ(Ω-cm) | | 2.1 × 10⁻⁴ | 2.6 × 10⁻³ | |
| Resistivityρₕ (Ω-cm) | | 1.8 × 10⁻² | 2.1 × 10⁻³ | |
| Reactive index n | ~2.4 | 2.36 | 3.01 | 1.9 |
| 1/(4λ) at λ = 0.6 μm (nm) | | 63.6 | 49.8 | 79.0 |
| Sheet resistance ρ_{□} (Ω/□) | | 33 (n) | 421 (p) | 27 (n) |

### DEFINITIONS

Herein, a notation is used to refer to alloys having the form of two sets of elements each within its own set of parenthesis; for example, (ABCD)(EFGH). This notation means that the alloy comprises at least one element selected from A, B, C, and D, and at least one element selected from E, F, G, and H. When this notation is used in combination with the modifiers such as “binary,” “ternary,” “quaternary,” “quinary,” or “senary,” among others, it means that the alloy contains a total of 2, 3, 4, 5, or even 6 elements, respectively, provided that at least one element selected from A, B, C, and D, and at least one element selected from E, F, G, and H. For example, a tertiary (BeZe)(SSeTe) alloy includes both BeZnSe and ZeSeTe, among other combinations.

It should be understood that when a layer is referred to as being “on” or “over” another layer or substrate, it can be directly on the layer or substrate, or an intervening layer may also be present. It should also be understood that when a layer is referred to as being “on” or “over” another layer or substrate, it may cover the entire layer or substrate, or a portion of the layer or substrate. It should be further understood that when a layer is referred to as being “directly on” another layer or substrate, the two layers are in direct contact with one another with no intervening layer. It should also be understood that when a layer is referred to as being “directly on” another layer or substrate, it may cover the entire layer or substrate, or a portion of the layer or substrate. In certain embodiments, a layer that is over another layer is directly on the other layer without any intervening layers in between.

The term “II-VI semiconductor” as used herein means an alloy where the constituent elements are selected from Groups IIA, IIB, and VIA, of the periodic table, wherein at least one constituent element is selected from Groups IIA and/or IIB of the periodic table and at least one constituent element is selected from Group VIA of the periodic table. Examples of

II-VI alloys include, but are not limited to (a) binary alloys such as, but not limited to, Cadmium selenide (CdSe), Cadmium sulfide (CdS), Cadmium telluride (CdTe), Zinc selenide (ZnSe), Zinc sulfide (ZnS), and Zinc telluride (ZnTe); (b) ternary alloy such as, but not limited to, Cadmium Zinc Telluride (CdZnTe, CZT), Beryllium Zinc Selenide BeₓZn₁₋ₓSe, wherein x is greater than 0 and less than 1 (e.g., Be_{0.45}Zn_{0.55}Se), (c) quaternary alloys such as, but not limited to, Cadmium zinc selenide telluride (CdZnSeTe).

The term “bandgap” or “E_{g}” as used herein means the energy difference between the highest occupied state of the valence band and the lowest unoccupied state of the conduction band of the material. The term “layer” as used herein, means a continuous region of a material (e.g., an alloy) that can be uniformly or non-uniformly doped and that has a uniform composition across the region.

The term “majority carrier” as used herein means the type of carrier in a majority amount compared to the other type of carrier in a material.

The term “minority carrier” as used herein means the type of carrier in a minority amount compared to the other type of carrier in a material. The term “p-doped” as used herein means atoms have been added to the material (e.g., an alloy) to increase the number of free positive charge carriers.

The term “n-doped” as used herein means atoms have been added to the material (e.g., an alloy) to increase the number of free negative charge carriers.

The term “p⁺-doped” as used herein means atoms have been added to the material (e.g., an alloy) to increase the number of free positive charge carriers such that the material is degenerate, as is known to those skilled in the art.

The term “n⁺-doped” as used herein means atoms have been added to the material (e.g., alloy) to increase the number of free negative charge carriers such that the material is degenerate, as is known to those skilled in the art. The term “p⁻-doped” as used herein means atoms have been added to the material (e.g., an alloy) to increase the number of free positive charge carriers with less density than the “p-doped” material.

The term “n⁻-doped” as used herein means atoms have been added to the material (e.g., alloy) to increase the number of free negative charge carriers with less density than the “n-doped” material.

The term “P-doped” as used herein means the material is p-doped, as defined herein, and the bandgap of the material is the same or greater than the p-doped material of a p-n junction.

The term “N-doped” as used herein means the material is n-doped, as defined herein, and the bandgap of the material is the same or greater than the n-doped material of a p-n junction.

The term “intrinsic” as used herein means a material without any intentional or unintentional doping.

The term “back surface field layer” as used herein means a layer of material that forms a barrier for minority carriers of the material adjacent to it such that the electric field in the junction of the two materials prevents the minority carriers from going into the back surface field layer.

The term “window layer” as used herein means a layer of material that has a large bandgap to pass most light into the layer of material below it, and it can also form minority carrier barriers for the layer of material below it.

The term “lattice matched” as used herein means that the two referenced materials have the same or lattice constants differing by up to +/−0.2%. For example, GaAs and AlAs are lattice matched, having lattice constants differing by ˜0.12%.

The term “pseudomorphically strained” as used herein means that layers made of different materials with a lattice parameter difference up to +/−2% can be grown on top of other lattice matched or strained layers without generating misfit dislocations. In certain embodiments, the lattice parameters differ by up to +/−1%. In other certain embodiments, the lattice parameters differ by up to +/−0.5%. In further certain embodiments, the lattice parameters differ by up to +/−0.2%.

The term “relaxed” as used herein means that the deformation potential generated by strain is released. The term “crystalline” as used herein means that the atoms are arranged in an orderly repeating pattern extending in all three spatial dimensions.

The term “amorphous” as used herein means atoms in a solid lacks the long range order.

The term “monocrystalline” as used herein means the crystal lattice of the entire sample is continuous and unbroken to the edges of the sample, with no grain boundaries.

The term “optical thickness” as used herein means the thickness multiplied by the refractive index of the layer.

### EXAMPLES

### Example 1

A first example is shown in FIG. 4. The embodiment chooses monocrystalline p⁻-Si as the absorbing layer (1) and pseudomorphically strained N⁺-ZnSe as the window layer (2).The pseudomorphically-strained high quality material ensures long carrier lifetimes. The back side of Si layer is p⁺ doped to form a back surface field region (3). The ZnSe layer has a large bandgap, and therefore little absorption in the solar spectrum range. The ZnSe layer thickness is made to reduce the series resistance and the front contact (4) area, and as an anti-refection coating optimized for the center wavelength 0.6 μm of the solar spectrum.

Using the bandgaps in Table I and reported band offset [19,20], the band alignment of the embodiment is calculated and plotted on the right hand side of FIG. 4. Under the incident light on the front surface, the majority carrier electrons and holes are swept into the N⁺-ZnSe and p⁻-Si layers by the electric field at the junction, respectively. The majority carrier electrons get through the spike in the conduction band of N⁺-ZnSe by tunneling or thermionic emission. The large valence band barrier in N⁺-ZnSe prevents most minority carrier holes from going into and recombining in N⁺-ZnSe and at the front contact (4). The conduction band barrier in the p⁻-Si back surface field layer prevents some of the minority carrier electrons from going into and recombining at the back contact (5).

### Example 2

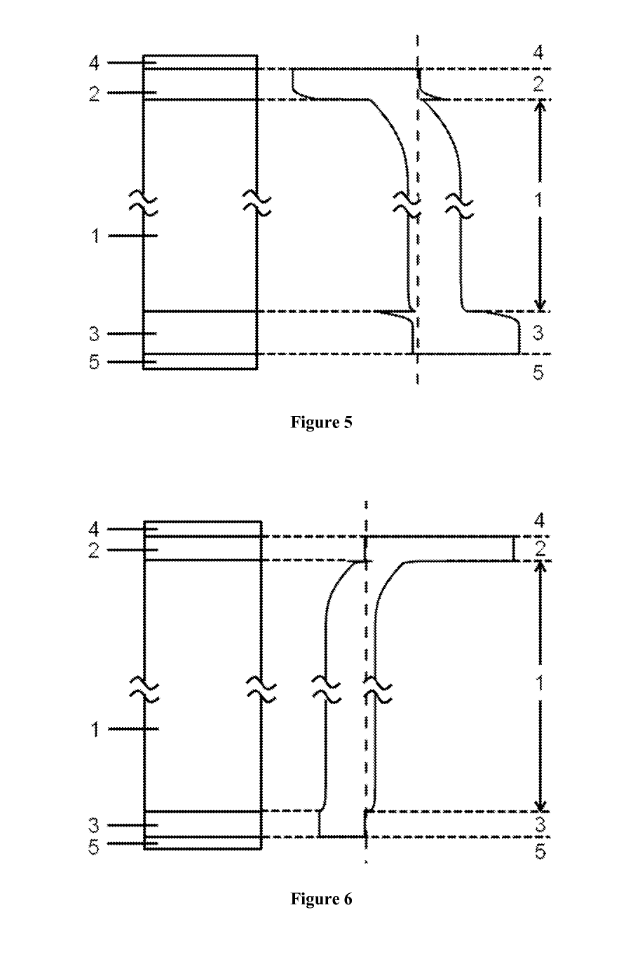

The second embodiment in FIG. 5 comprises the elements of the first embodiment with a P⁺-ZnTe layer (3) in replacement of the p⁺-Si back surface field layer. The P⁺-ZnTe forms a large conduction band barrier at the interface with p⁻-Si. Therefore, the P⁺-ZnTe layer is more effective than the p⁺-Si layer in blocking minority carrier electrons from going into and recombining at the back contact.

### Example 3

The third embodiment as shown in FIG. 6 uses monocrystalline n⁻-Si as the absorbing layer (1) and P⁺-Be_{0.45}Zn_{0.55}Se as the window layer (2).Because Be_{0.45}Zn_{0.55}Se is perfectly lattice matched to Si, the interface between them is expected to be defect free. Furthermore, Be_{0.45}Zn_{0.55}Se is an indirect bandgap material with bandgap about 3.7 eV (see FIG. 7[17,18]), therefore the absorption loss is negligible. Therefore, compared to the first and second embodiments, this embodiment can achieve higher efficiency due to much longer carrier lifetime in n-type Si and much better interface properties. The Be_{0.45}Zn_{0.55}Se layer thickness is made to reduce the series resistance and the front contact (4) area, and as an anti-refection coating optimized for the center wavelength 0.6 μm of the solar spectrum. Upon light irradiation, the large conduction band barrier in the P⁺- Be_{0.45}Zn_{0.55}Se layer and the valence band barrier formed by the n⁺-Si back surface field layer (3) prevent most minority carrier electrons and some minority carrier holes from going into and recombining in the respective layer and the corresponding contact (4,5).

### Example 4

The forth embodiment in FIG. 8 comprises the elements of the third embodiment with a N⁺-Be_{0.45}Zn_{0.55}Se layer (3) in replacement of the n⁺-Si back surface field layer. The N⁺-Be_{0.45}Zn_{0.55}Se layer forms a large valence band barrier at the interface with Therefore, the N⁺-ZnSe layer is more effective than the n⁺-Si back surface field layer in blocking minority carrier holes from going into and recombining at the back contact.

### REFERENCES

[1] M. GAM, A. Storzuma, M. Hettericha, A. Kamillib, W. Sendb, Th. Walterb, and C. Klingshirn, J. Cryst. Growth 201/202, 457 (1999).

[2] Y. Tsunomura, Y. Yoshiminea, M. Taguchia, T. Babaa, T. Kinoshitaa, H. Kannoa, H. Sakataa, E. Maruyamaa, and M. Tanakaa, Solar Energy Materials and Solar Cells, 93, 670 (2008).

[3] M. GAM, A. Storzuma, M. Hettericha, A. Kamillib, W. Sendb, Th. Walterb, and C. Klingshirn, J. Cryst. Growth 201/202, 457 (1999).

[4] S. Kishimoto, T. Hasegawa, H. Kinto, O. Matsumoto, and S. Iida, J. Cryst. Growth 214/215, 556 (2000).

[5] Y .Imanaka and N. Miura, Phys. Rev. B 50, 14065 (1994).

[6] G A. Samara, Phys. Rev. B 27, 3494 (1983).

[7] D. L. Rode, Phys. Rev. B 2, 4036 (1970)

[8] S. Adachi and T. Taguchi, Phys. Rev. B 43, 9569 (1991).

[9] H. Goto, T. Ido, and A. Takatsuka, J. Cryst. Growth 214/215, 529 (2000).

[10] S. G. Parker, J. E. Pinnell, and L. N. Swink, J. Phys. Chem. Solids 32, 139 (1971).

[11] M. Drechsler, B. K. Meyer, D. M. Hofmann, P. Ruppert, and D. Hommel, Appl. Phys. Lett. 71, 1116 (1997).

[12] J. Qiu, J. M. DePuydt, H. Cheng, M. A. Haase, Appl. Phys. Lett. 59, 2992 (1991).

[13] W. Stutius, Appl. Phys. Lett. 38, 352 (1981).

[14] G. E. Hite, D. T. F. Marple, M. Aven, and B. Segall, Phys. Rev. 156, 850-859 (1967).

[15] H. P. Wagner, S. Lankes, K. Wolf, W. Kuhn, P. Link, and W. Gebhardt, J. Cyst. Growth 117, 303 (1992).

[16] S. Adachi, Handbook on physical properties of semiconductors, (Kluwer, Boston, 2004).

[17] K. Wilmers, T. Wethkamp, N. Esser, C. Cobet, W. Richter, V. Wagner, H. Lugauer, F. Fischer, T. Gerhard, M. Keim, and M. Cardona, J. Electron. Mater. 28, 670 (1999).

[18] A. Bukaluk, A. A. Wronkowska, A. Wronkowski, H. Arwin, F. Firszt, S. Legowski, H. Meczynska, and J. Szatkowski, Appl. Surf. Sci. 531,175 (2001).

[19] S. Adachi, Handbook on physical properties of semiconductors, (Kluwer, Boston, 2004).

[20] L. C. Lew Yan Voon, L. R. Ram-Mohan and R. A. Soref, Appl. Phys. Lett. 70, 1837 (1997).

The present invention is illustrated by way of the foregoing description and examples. The foregoing description is intended as a non-limiting illustration, since many variations will become apparent to those skilled in the art in view thereof. It is intended that all such variations within the scope and spirit of the appended claims be embraced thereby. Each referenced document herein is incorporated by reference in its entirety for all purposes. Changes can be made in the composition, operation and arrangement of the method of the present invention described herein without departing from the concept and scope of the invention as defined in the following claims.

1. A photovoltaic device comprising,
a first contact electrode;
a first doped II-VI semiconductor layer disposed over the first contact electrode;
a doped crystalline silicon layer disposed over the first doped II-VI semiconductor layer; and
a second contact electrode disposed over the doped silicon layer,
wherein one of the doped crystalline silicon layer and the first doped II-VI semiconductor layer is n-doped and the other is p-doped.

2. The photovoltaic device of claim 1, further comprising a second doped II-VI semiconductor layer disposed between the doped crystalline silicon layer and the second contact electrode, wherein the second doped II-VI semiconductor layer is of the same doping type as the doped crystalline silicon layer.

3. The photovoltaic device of claim 1, wherein the first doped II-VI semiconductor layer, and the second doped II-VI semiconductor layer, when present, each independently comprise a (BeZn)(SSeTe) alloy layer.

4. The photovoltaic device of claim 3, wherein the first doped II-VI semiconductor layer, and the second doped II-VI semiconductor layer, when present, each independently comprise ZnTe, ZnSe, ZnS, or BeₓZn₁₋ₓSe, wherein x is greater than 0 and less than 1.

5. The photovoltaic device of claim 1, wherein the first doped II-VI semiconductor layer, and the second doped II-VI semiconductor layer, when present, each are pseudomorphically strained or partially relaxed to silicon.

6. The photovoltaic device of claim 1, wherein the first doped II-VI semiconductor layer, and the second doped II-VI semiconductor layer, when present, each have bandgaps larger than silicon.

7. The photovoltaic device of claim 1, wherein the first doped II-VI semiconductor layer has an optical thickness equal to a quarter of the center wavelength of the solar spectrum.

8. The photovoltaic device of claim 7, further comprising a transparent conductive oxide layer disposed between the first doped II-VI semiconductor layer and the first contact electrode.

9. The photovoltaic device of claim 1, wherein the doped crystalline silicon layer comprises single crystalline silicon, multicrystalline silicon, or polycrystalline silicon.

10. The photovoltaic device of claim 1, wherein the surface of the doped crystalline silicon layer in contact with the first doped II-VI semiconductor layer is textured.

11. The photovoltaic device of claim 2, wherein the surface of the doped crystalline silicon layer in contact with the second contact electrode or the second II-VI semiconductor layer, when present, is textured.

12. The photovoltaic device of claim 1 wherein the first contact electrode is a metal grid, and the second contact electrode is a metal grid, one or more point metal contacts, or a continuous metal contact layer.

13. The photovoltaic device of claim 1, comprising,
a first contact electrode;
a first doped Be_{0.45}Zn_{0.55}Se layer disposed over the first contact electrode;
a doped crystalline silicon layer disposed over the first doped Be_{0.45}Zn_{0.55}Se layer; and
a second contact electrode disposed over the doped silicon layer,
wherein one of the doped crystalline silicon layer and the first doped II-VI semiconductor layer is n-doped and the other is p-doped.
